(19) United States
(12) Patent Application Publication
(10) Pub. No.: US 2008/0277708 A1
(43) Pub. Date: Nov. 13, 2008

(54) SEMICONDUCTOR DEVICES AND METHODS OF FORMING THE SAME

(75) Inventor: Chear-Yeon MUN, Yogin-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/117,627

(22) Filed: May 8, 2008

(30) Foreign Application Priority Data
May 11, 2007 (KR) 10-2007-0046065

(51) Int. Cl. H01L 29/94; H01L 21/8236

(52) U.S. Cl. 257/296; 438/278; 257/E21.632; 257/E29.345

(57) ABSTRACT

A highly integrated semiconductor device has a device isolation layer demarcating a first active region in a first region of a substrate, and a second active region in a second region of the substrate. A first gate pattern and a second gate pattern are formed on the first active region and the second active region, respectively. A first spacer layer and a second spacer layer are formed over the gate patterns. Then, the second and first spacer layers in the first region are anisotropically etched to form a gate spacer on sidewalls of the first gate pattern. The gate spacer has a lower spacer section formed from the first spacer layer and an upper spacer section formed from the second spacer layer. Then, ions are implanted into the first active region. Subsequently, the upper spacer section and the second spacer layer on the first and second regions, respectively, are removed. A selective growth process is then performed to form a buffer insulating layer on the first active region beside the lower spacer sections. An etch stop layer and an interlayer dielectric may be then formed on the substrate.

### BACKGROUND OF THE INVENTION

The present invention relates to semiconductor devices and to methods of forming the same. More particularly, the present invention relates to highly integrated semiconductor devices and to methods of forming the same.

Semiconductor devices may be formed by performing numerous semiconductor fabrication processes on a semiconductor substrate. Semiconductor fabrication processes may include processes forming various types of material layers on a semiconductor substrate, photolithography processes that define semiconductor patterns, processes of etching the material layers and/or the semiconductor substrate, processes for implanting dopants, and/or cleaning processes. These various types of semiconductor fabrication processes are performed while maintaining organic interaction, to allow the fabrication of many different types of semiconductor devices.

The fabricating of today's semiconductor devices is aimed at providing the devices with high degrees of integration and diverse functions. Thus, the fabrication processes are correspondingly complex. As the complexity of these semiconductor fabrication processes increases, the manufacturing yield of the semiconductor devices tends to decrease. Also, the process margins for the semiconductor fabrication processes are becoming smaller because the design CDs (critical dimensions) of the patterns of the devices, e.g., the line widths of the patterns and/or gaps between the patterns of the devices, are constantly being reduced to meet the demand for more highly integrated devices. At the same time, there is a growing demand for semiconductor devices having distinctive qualities, such as low heat radiation, durability in thermally deleterious environments, and high-speed operation. As a result of these demands, advancements in the semiconductor industry are occurring at a blindingly fast pace. Therefore, current research is focused on not only providing such devices but designing such devices so that their fabrication can be carried out with a high yield.

### SUMMARY OF THE INVENTION

An object of the present invention is to provide a highly integrated semiconductor device optimized for high integration.

Another object of the present invention is to provide a highly integrated semiconductor device having exemplary characteristics.

Still another object of the present invention is to provide an efficient method of manufacturing a highly integrated semiconductor device.

Another object of the present invention is to provide a method of manufacturing a highly integrated semiconductor device which ensures that voids are not formed in a gap region between adjacent gate patterns disposed in the same region of the device.

According to one aspect of the present invention, there is provided a method of manufacturing a semiconductor device in which a selective growth process is used to form an insulating buffer layer which alleviates stress between an active region and an etch stop layer. A device isolation layer is formed on a substrate to demarcate a first active region in a first region of the substrate and a second active region in a second region of the substrate. A first gate pattern and a second gate pattern are then formed on the first active region and the second active region, respectively. Next, a first spacer layer and a second spacer layer are formed in sequence each over the entirety of the substrate. The second and first spacer layers on the first region are anisotropically etched to form a gate spacer. The gate spacer has a lower spacer section formed from the first layer and an upper spacer formed from the second spacer layer on each sidewall of the first gate pattern. At this time, the second and first spacer layers are left on the second region. Subsequently, the upper spacer sections of the gate spacer on the sidewalls of the first gate pattern are removed, and the second spacer layer on the second region is removed. The aforementioned selective growth process is then carried out to form the buffer insulating layer on the first active region beside the lower spacer sections remaining on the sidewalls of the first gate pattern. Preferably, the buffer insulating layer has a thickness of from about 5 Å to about 50 Å. Next, an etch stop layer and an interlayer dielectric are sequentially formed over the entirety of the substrate. Preferably, the etch stop layer comprises a nitride layer.

The selective growth process may be a wet oxidation process. The wet oxidation process may employ an oxidation solution including hydrogen peroxide. The oxidation solution may further include sulfuric acid. Alternatively, the selective growth process may be a thermal oxidation process. Also, to facilitate the selective aspect of the growth process, the first spacer layer may be formed of an insulating material which prevents the material constituting the buffer insulating layer from growing thereon.

Also, the substrate may be subjected to a gate oxidation process before the first spacer layer is formed to form an oxide layer on the first and second active regions at both sides of each of the first and second gate patterns. In this case, the oxide layer formed on the first active region beside the lower spacer sections of the gate spacer is removed together with the upper spacer sections of the gate spacer and the second spacer layer on the second region.

In addition, an opening may be formed in the interlayer dielectric, the etch stop layer, and the buffer insulating layer to expose the first active region at one side of the first gate pattern. The opening is subsequently filled with conductive material to form a conductive plug.

According to another aspect of the invention, there is provided a method of manufacturing a semiconductor device which decreases the aspect ratio between adjacent gate patterns before an interlayer dielectric is formed over the gate patterns. A device isolation layer is formed on a substrate to demarcate a first active region in a first region of the substrate and a second active region in a second region of the substrate. A first gate pattern is then formed on the first active region and several second gate patterns are formed on the second active region. Next, at least one spacer layer is formed over the entirety of the substrate. The at least one spacer layer on the first region is anisotropically etched to form a gate spacer. At this time, the at least one spacer layer is left on the second region. Next, dopant ions are implanted into the first region of the substrate using the first gate pattern and the gate spacer as a mask. Subsequently, the at least one spacer layer is simultaneously etched on the first and second active regions, thereby decreasing the aspect ratio of the space between adjacent ones of the second gate patterns. An interlayer dielectric is them formed over the entirety of the substrate.

According to another aspect of the present invention, there is provided a semiconductor device including a gate spacer consisting of L-shaped spacer sections respectively disposed on the sidewalls of a gate pattern on one region of a substrate, and a spacer layer of the same material as the spacer sections covering at least one gate pattern on a second region of the substrate. More specifically, a device isolation layer demarcates a first active region in a first region of the substrate and a second active region in a second region of the substrate. The first gate pattern and the second gate pattern(s) are respectively disposed on the first active region and the second active region. The L-shaped sections of the gate spacer are disposed on the sidewalls of the first gate pattern, respectively. A buffer insulating layer is disposed on the first active region beside the gate spacer. The aforementioned spacer layer conformally covers the second gate pattern on the second region and the second active region. Also, an etch stop layer covers the entirety of the substrate, and an interlayer dielectric is disposed on the etch stop layer.

The etch stop layer preferably contacts the buffer insulating layer, the gate spacer, and the spacer layer. The buffer insulating layer may be an oxide layer formed by a selective growth process. The etch stop layer may be a nitride layer. The semiconductor device may also include an oxide layer interposed between the gate spacer and the first active region, and between the spacer layer and the second active region. The semiconductor device may also have a conductive body extending through the interlayer dielectric, the etch stop layer, and the buffer insulating layer in the first region, and contacting the first active region at one side of the first gate pattern.

### BRIEF DESCRIPTION OF THE DRAWINGS

The present invention will be better understood form the detailed description of the preferred embodiments thereof which follows with reference to the accompanying drawings. In the drawings:

FIGS. 1A, 2A . . . 8A are each a plan of a substrate, and FIGS. 1B, 2B . . . 8B are each a sectional view of the substrate taken along lines I-I′ of FIGS. 1A, 2A . . . 8A, respectively, and collectively illustrate a method of manufacturing a semiconductor device according to the present invention;

FIG. 9A is a plan view of a substrate illustrating a method of forming a conductor connected to a first source/drain region according to the present invention;

FIG. 9B is a sectional view of the substrate taken along line I-I′ of FIG. 9A;

FIG. 10A is a plan view of a semiconductor device according to the present invention; and

FIG. 10B is a sectional view of the semiconductor device taken along line II-II′ of FIG. 10A.

### DETAILED DESCRIPTION OF PREFERRED EMBODIMENTS

The present invention will be described below in more detail with reference to the accompanying drawings. It is to be noted, though, that the dimensions of layers and regions are exaggerated in the drawings for clarity of illustration. Also, like reference numerals designate like elements throughout the drawings.

Furthermore, when a layer (or film) is referred to in the written description as being ‘on’ another layer or substrate, it means that such a layer (or film) can be directly on the other layer or substrate, or that one or more other layers may be present therebetween. Also, when a layer (or film) is referred to as being ‘under’ another layer, it means that the layer (or film) can be directly under the other layer, or that one or more other layers may be present therebetween. In addition, when a layer (or film) is referred to as being ‘between’ two layers, it means that the layer (or film) may be the only layer (or film) between the two layers, or that one or more other layers may also be present between the two layers.

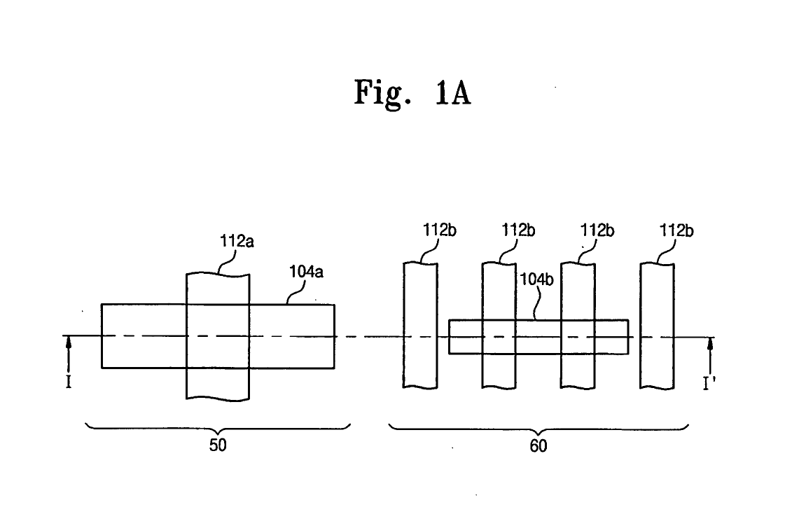

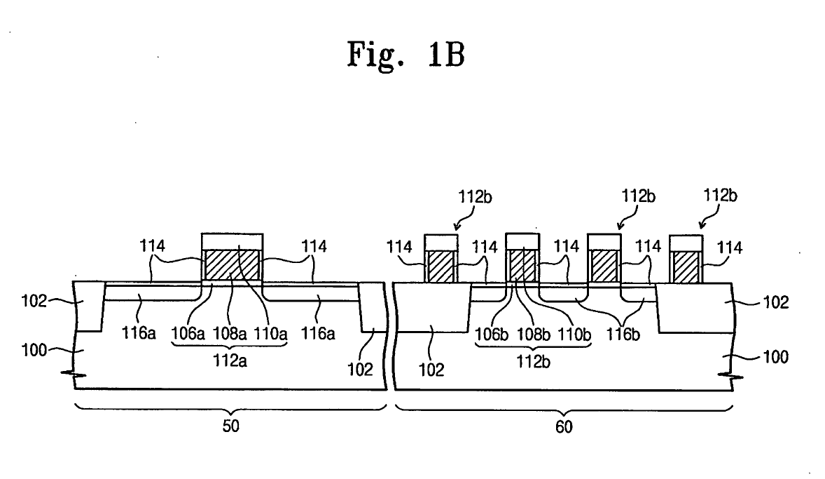

Referring now to FIGS. 1A and 1B, a semiconductor substrate 100 (referred to hereinafter as merely a “substrate”) is prepared. In this respect, the semiconductor substrate 100 includes a first region 50 and a second region 60. The first region 50 may include a peripheral circuit region, and the second region 60 may include a cell region on which a memory cell is formed. In the present embodiment, the second region 60 may include a cell region on which dynamic random access memory (DRAM) cells are formed.

Also, a device isolation layer 102 is formed on the substrate 100 to isolate a first active region 104a in the first region 50 and a second active region 104b in the second region 60. More specifically, the substrate 100 may have a plurality of second active regions 104b in the second region 60. The second active regions 104b may be arrayed two-dimensionally, i.e., in a number of rows and columns. In this case, the even-numbered columns of the second active regions 104b are preferably separated from the odd-numbered columns of the second active regions 104b, respectively, by one-half the columnar pitch of the odd-numbered columns of second active regions 104b.

A first gate pattern 112a and a second gate pattern 112b are respectively formed in the first region 50 and the second region 60. The first gate pattern 112a intersects the first active region 104a, and the second gate pattern 112b intersects the second active region 104b. More than one second gate pattern 112b may be formed in the second region 60, however. In particular, a plurality of parallel second gate patterns 112b may be formed on the substrate 100 within the second region 60. In this case, a pair of adjacent second gate patterns 112b intersects each of the second active regions 104b in one of the columns of the second active regions 104b.

The first gate pattern 112a may include a first gate dielectric 106a, a first gate electrode 108a, and a first gate cap 110a that are stacked one atop the other in the foregoing sequence. The second gate pattern 112b may include a second gate dielectric 106b, a second gate electrode 108b, and a second gate cap 110b stacked one atop the other in the foregoing sequence. The first gate dielectric 106a may be a thermal oxide layer. The first gate electrode 108a may include at least one material selected from the group consisting of a doped polysilicon (e.g., polysilicon doped with tungsten, or molybdenum), a conductive metal nitride (e.g., titanium nitride, or tantalum nitride), and a metal silicide (e.g., tungsten silicide, or cobalt silicide). The first gate cap 111a is formed of an insulating material. In particular, the first gate cap 111a may particularly be formed of an insulating material having an etch selectivity with respect to an interlayer dielectric formed thereafter. As an example, the first gate cap 110a may be formed of a nitride such as silicon nitride or oxidized silicon nitride. The second gate dielectric 106b may be of the same or different thickness as the first gate dielectric 106a. Also, the first and second gate dielectrics 106a and 106b may be formed of the same material. The second gate electrode 108b and the second gate cap 110b may be formed of the same materials as the first gate electrode 108a and the first gate cap 110a, respectively.

Subsequently, the first and second gate patterns 112a and 112b may be subjected to a gate oxidation process. An oxide layer 114 is formed by the gate oxidation process. The oxide layer 114 is formed on the sidewalls of the first and second gate electrodes 108a and 108b. Also, the oxide layer 114 is formed on the first and second active regions 104a and 104b at the sides of the first and second gate patterns 112a and 112b.

Next, first dopant ions are implanted in the first active region 104a, using the first gate pattern 112a as a mask. As a result, a first source/drain region 116a is formed on the first active region 104a at the sides of the first gate pattern 112a. Also, second dopant ions are implanted in the second active region 104b, using the second gate pattern 112b as a mask. Thus, a second source/drain region 116b is formed on the second active region 104b at the sides of the second gate pattern 112b. Note, the oxide layer 114 formed on the first and second active regions 104a and 104b acts as an ion implantation buffer layer during the implanting of the first and second dopant ions.

The first dopant ions and the second dopant ions may be of the same material. Also, the doses at which the first and second dopant ions are implanted may also be the same. In these instances, the first and second source/drain regions 116a and 116b may be simultaneously formed. Alternatively, the first and second source/drain regions 116a and 116b are sequentially formed when the first dopant ions and the second dopant ions are of different materials or the doses at which the first and second dopant ions are implanted are different. In this case, a photosensitive layer is formed on the substrate 100 and patterned (not shown) to cover the second region 60. Then, the first active region 104a is doped to form the first source/drain region 11 6a. Subsequently, a photosensitive layer pattern is formed on the substrate 100 and patterned (not shown) so as to cover the first region 50. Then, the second active region 104b is doped to form the second source/drain region 116b. Conversely, though, the first source/drain region 116a may be formed after the second source/drain region 116b.

In any case, the first gate pattern 112a and the first source/drain region 116a constitute a first transistor, and the second gate pattern 112b and the second source/drain region 116b constitute a second transistor. The first transistor may be part of a peripheral circuit, whereas the second transistor may be a transistor of a DRAM cell.

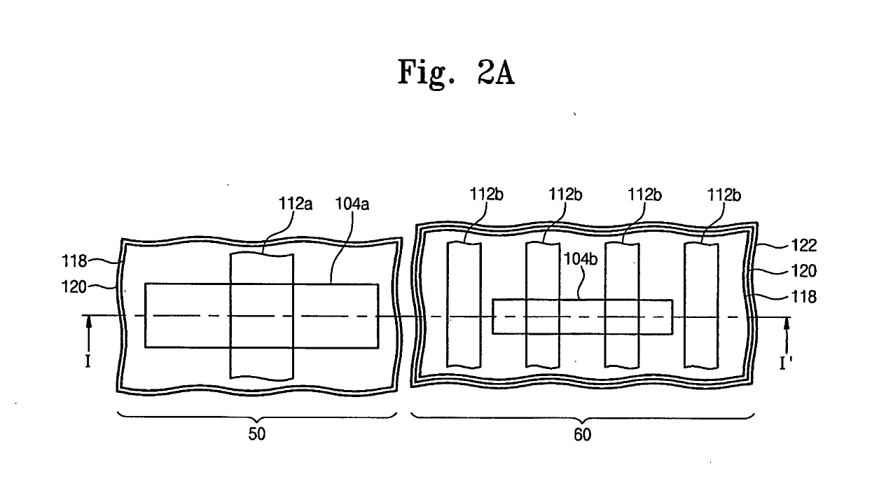

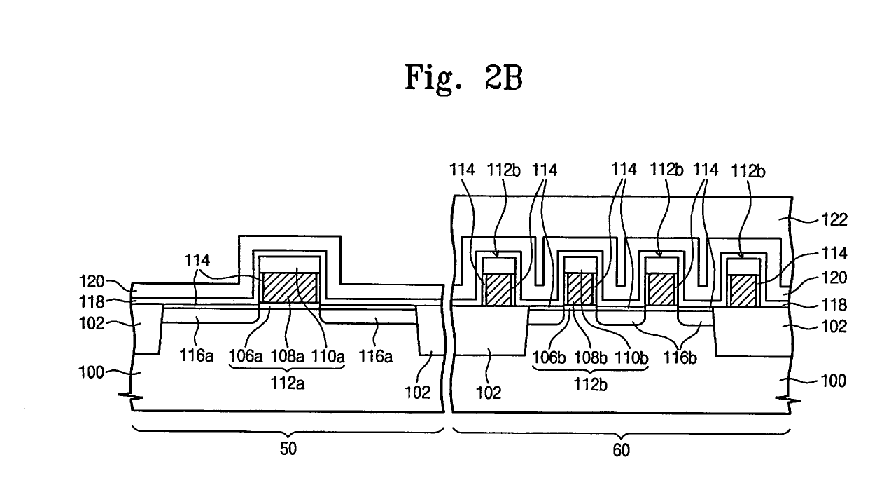

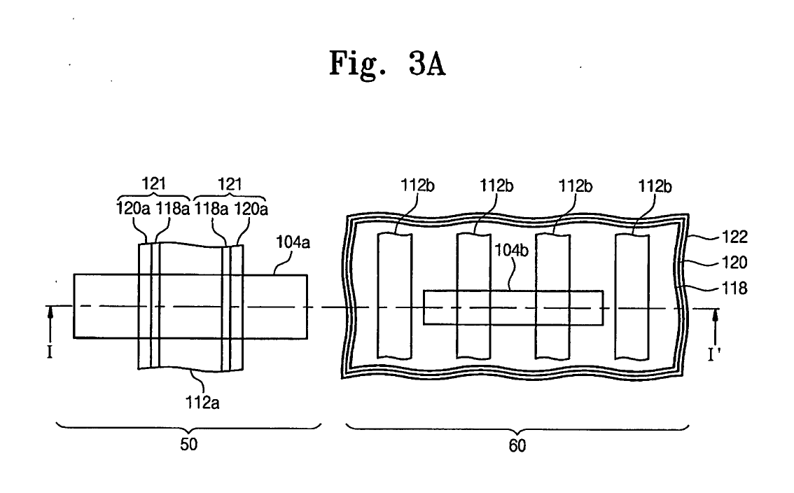

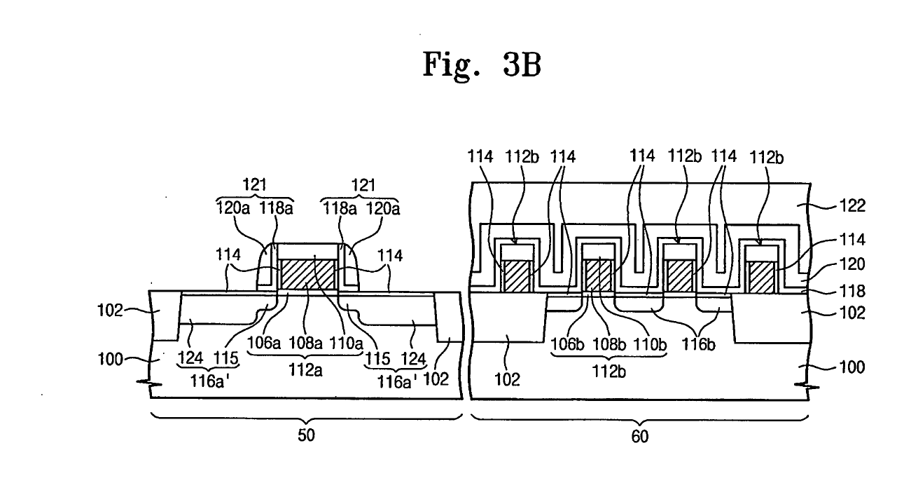

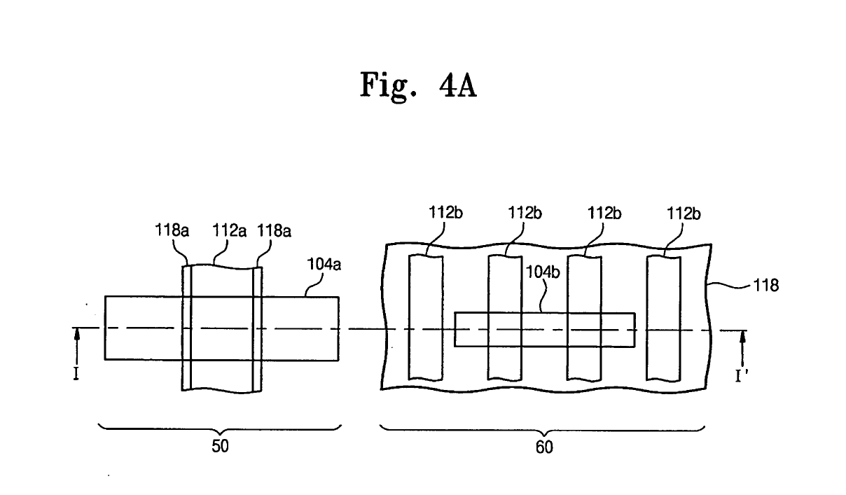

Referring to FIGS. 2A and 2B, next, a first spacer layer 118 and a second spacer layer 120 are sequentially formed on the substrate 100. The first and second spacer layers 118 and 120 may be conformal layers (layers that conform to the topography of the underlying structure). The first spacer layer 118 may be formed of an insulating material that can protect the first and second gate electrodes 108a and 108b during subsequent etching processes. Also, the first spacer layer 118 is formed on the first and second source/drain regions 116a and 116b atop the oxide layer 114. Thus, the oxide layer 114 minimizes stress (tensile stress, for example) between the first spacer layer 118 and the upper surfaces of the first and second source drain regions 116a and 116b, i.e., the upper surfaces of the first and second active regions 104a and 104b. The second spacer layer 120 may be formed of an insulating material that has an etch selectivity with respect to the first spacer layer 118. For example, the second spacer layer 120 may be a chemical vapor deposition (CVD) oxide layer. The first spacer layer 118 will be described in more detail below.

Next, a mask pattern 122 is formed to cover the portion of the second spacer layer 120 extending on the second region 60 of the substrate 100. On the other hand, the portion of the second spacer layer 120 extending on the first region 50 is exposed by the mask pattern 122.

Referring to FIGS. 3A and 3B, the portions of the second and first spacer layers 120 and 118 extending on the first region 50 are anisotropically etched using the mask pattern 122 as an etch mask. Accordingly, a gate spacer 121 is formed the sides of the first gate pattern 112a. The gate spacer 121 includes a lower spacer 118a and an upper spacer 120a that is disposed over the lower spacer 11 8a. The lower spacer 11 8a has an “L” shape. Also, at this time, the oxide layer 114 is left remaining on the first active region 104a beside the gate spacer 121.

Next, the mask pattern 122, third dopant ions are implanted into the first source/drain region 116a using the first gate pattern 112a and the gate spacer 121 as a mask. The third dopant ions are of the same type as the first dopant ions. Also, the dose of the third dopant ions may be greater than the dose of the first dopant ions. Accordingly, a linear dynamic deposition (LDD) type of first source/drain region 116a′ is formed on the first active region 104a at the sides of the first gate pattern 112a. The LDD first source/drain region 116a′ includes a low concentration region 115, and a high concentration region 124 formed on the first active region 104a beside the low concentration region 115. The high concentration region 124 has a higher density of dopant than the low concentration region 115. The second source/drain region 116b may also have a lower dopant concentration than the high concentration region 124.

The low concentration region 115 is a region formed by implanting the first dopant ions. The oxide layer 114 on the first active region 104a is used as an ion buffer layer during the implanting of the third dopant ions. The width of the low concentration region 115 (that is, the distance between the channel region defined below the first gate pattern 112a and the high concentration region 124) is defined by the width of the upper spacer 120a (that is, the thickness of the second spacer layer 120).

Thus, the second spacer layer 120 may be formed to a thickness which will create the desired width of the low concentration region 115. The width of the low concentration region 115 can determine the characteristics of the first transistor. For example, the smaller the width of the low concentration region 115, the greater is the magnitude of the current required to turn the first transistor on, and vice versa.

Referring to FIGS. 4A and 4B, next, the mask pattern 122 is removed to expose the second spacer layer 120 on the second region 60. Then, the second spacer layer 120 on the second region 60 is removed. At this time, the upper spacer 120a is also removed. Also, the oxide layer 114 beside the lower spacer 11 8a is removed to expose a portion of the upper surface of the first source/drain region 116a′ (in particular, the upper surface of the high concentration region 124). Preferably, the upper spacer 120a and the second spacer layer 120 of the second region 60, and the oxide layer 114 on the high concentration region 124 are simultaneously removed by wet etching. Thus, it is possible to prevent the exposed surface of the first active region 104a from being damaged, unlike a dry etching process using plasma.

Moreover, the aspect ratio of a gap region between adjacent second gate patterns 112b is reduced when the second spacer layer 120 on the second region 60 is removed. Thus, voids are less likely to occur in the material subsequently deposited on the substrate 100 to fill the cap region.

The lower spacer 118a and the first spacer layer 118 on the second region 60 have an etch selectivity with respect to the second spacer layer 120. Thus, the lower spacer 118a and the first spacer layer 118 on the second region 60 protect the first and second gate patterns 112a and 112b particularly the first and second gate electrodes 108a and 108b) from the etchant used for removing the spacer layer 120 from atop the second region 60.

Referring to FIGS. 5A and 5B, next, a selective growth process is performed on the substrate 100 to form a buffer insulating layer 126 on the exposed first active region 104a. In this respect, the insulating material of the first spacer layer 118 is selected to prevent the buffer insulating layer 126 from forming on the lower spacer 118a and the first spacer layer 118 in the first and second regions 50 and 60. For example, the first spacer layer 118 may be a nitride layer (e.g., a silicon nitride layer or a silicon oxide nitride layer), and the buffer insulating layer 126 may be an oxide layer. Thus, the buffer insulating layer 126 is formed only on the exposed first active region 104a. The buffer insulating layer 126 preferably has a thickness of from about 5 Å to about 50Å.

The selective growth process may be a wet oxidation process. The wet oxidation process may employ an oxidizing liquid. That is, oxidizing liquid may be provided on the substrate 100 to form the buffer insulating layer 126 on the exposed first active region 104a. To this end, the oxidizing liquid may include hydrogen peroxide (H₂O₂) which has strong oxidizing properties. In this case, the wet oxidation process may be carried out for several to several hundred seconds. Furthermore, the oxidizing liquid may also include sulfuric acid (H₂SO₄). Sulfuric acid in the oxidizing liquid can remove organic contaminants from the exposed surface of the first active region 104a during the selective growth process.

Alternately, the selective growth process may be a thermal oxidation process in which the substrate 100 is exposed to process gas which will oxidize the exposed first active region 104a. The processing gas used in the thermal oxidation process may include oxygen gas and/or water vapor. The oxidation process is performed at a processing temperature of several hundred ° C. Preferably, the thermal oxidation process is performed at a temperature of from about 800° C. to about 900° C.

Next, an etch stop layer 128 and a first interlayer dielectric 130 are formed successively over the entire surface of the substrate 100. The etch stop layer 128 may be an insulating layer having an etch selectivity with respect to the first interlayer dielectric 130. The etch stop layer 128 preferably has a substantially uniform thickness. The first interlayer dielectric 130 may be a CVD oxide layer. For example, the first interlayer dielectric 130 may include at least one layer selected from the group consisting of boron phosphorous silicate glass (BPSG), PSG, BSG, undoped SG (USG), tetraethoxysilane (TEOS), and methyltrioxorhenium (MTO). Also, when the first interlayer dielectric 130 includes a BPSG layer, a BSG layer, and/or a PSG layer, the etch stop layer 128 can prevent impurities in the first interlayer dielectric 130 (e.g., boron and/or phosphorous) from diffusing to the first and second source/drain regions 116a′ and 116b. To this end, the etch stop layer 128 may include a nitride layer (e.g., a silicon nitride layer and/or a silicon oxide nitride layer).

The etch stop layer 128 is formed atop the high concentration region 124 on the buffer insulating layer 126. Thus, even if the etch stop layer 128 is formed of a nitride layer, the buffer insulating layer 126 functions to buffer stress between the etch stop layer 128 and the first source/drain region 116a′. Also, the buffer insulating layer 126 is not formed on the second region 60. Accordingly, the aspect ratio of the gap region between adjacent first gate patterns 112b remains relatively low while the etch stop layer 128 and the first interlayer dielectric 130 are formed. As a result, the etch stop layer 128 and the first interlayer dielectric 130 can be formed without voids occurring in the gap region.

As described above, the buffer insulating layer 126 is formed through a selective growth process according to the present invention. Therefore, the present invention obviates a need to selectively remove the buffer insulating layer from atop the second region 60 of the substrate 100 (which would entail forming a photosensitive layer pattern to cover the first region 50, etching the buffer insulating layer on the second region 60 using the photosensitive layer pattern as an etch mask, removing the photosensitive layer pattern, and cleaning the resultant structure). That is, the present invention minimizes the number of semiconductor fabrication processes and thereby can maximize the yield.

Referring to FIGS. 6A and 6B, the first interlayer dielectric 130 on the first region 50, the etch stop layer 128, and the buffer insulating layer 126 are successively patterned to form a lower opening 132 exposing the first source/drain region I 16a′ at a side of the first gate pattern 112a. Also, the first interlayer dielectric 130 on the second region 60, the etch stop layer 128, the first spacer layer 118, and the oxide layer 114 are successively patterned to form a first land opening 134a and a second land opening 134b respectively exposing the second source/drain regions 116b at first and second sides of the second gate pattern 112b. The lower, first, and second land openings 132, 134a, and 134b may be simultaneously formed.

The lower opening 132 is formed next to the lower spacer 118a. That is, the lower opening 132 exposes the high concentration region 124 of the first source/drain region 116a′. On the other hand, the first and second land openings 134a and 134b expose the second source/drain region 116b. More specifically, as the insulating layer 130 is etched to form the first and second land openings 134a and 134b, the etch stop layer 128 on the sidewalls of the second gate patterns 112b become exposed, and the first spacer layer 118 on the sidewalls of the second gate patterns 112b also become exposed. As a result, spacer-shaped patterns 118′, 128′ are formed on the sidewalls of the second gate patterns 112b. Thus, the area of the first and second land openings 134a and 134b is maximized and yet only the source/drain regions 116b are exposed.

Next, a first conductive layer is formed to fill the lower, first, and second land openings 132, 134a, and 134b, and the first conductive layer is continually planarized until the first interlayer dielectric 130 is exposed. As a result, a conductive plug 136, a first landing pad 138a, and a second landing pad 138b are formed as respectively occupying the lower opening 132, the first land opening 134a, and the second land opening 134b. The conductive plug 136, the first landing pad 138a, and the second landing pad 138b preferably include at least one material selected from the group consisting of doped polysilicon, pure metals (e.g., titanium, tantalum, and tungsten) and conductive metal nitrides (e.g., titanium nitride and tantalum nitride). Also, as is clear from the description above, through this process the first landing pad 138a and second landing pad 138b are formed as self-aligned with respective ones of the source/drain regions 116b. Also, electrical shorts between the first and second landing pads 138a and 138b and the second gate electrode 108b are prevented.

The second landing pad 138b may extend in a lengthwise direction of the first gate pattern 112b such that a portion of the second landing pad 138b overlies the device isolation layer 102. Preferably, therefore, the second landing pad 138b is longer than the first landing pad 138a (i.e., the dimension of the second landing pad 138b as measured in the lengthwise direction of the second gate pattern 112b is greater than the dimension of the first landing pad 138a as measured in the lengthwise direction of the second gate pattern 112b).

Referring to FIGS. 7A and 7B, next, a second interlayer dielectric 140 is formed over the entire substrate 100. The second interlayer dielectric 140 may be a CVD oxide layer.

The second interlayer dielectric 140 is patterned to form an upper opening 142a and a bit line contact hole 142b. The upper opening 142a exposes the upper surface of the conductive plug 136, and the bit line contact hole 142b exposes the upper surface of the second landing plug 138b. The bit line contact hole 142b may expose the upper surface of the portion of the second landing pad 138a which overlies the device isolation layer 102.

A second conductive layer is formed to fill the upper opening 142a and bit line contact hole 142b, and the second conductive layer is planarized until the second interlayer dielectric 140 is exposed. As a result, a wiring plug 144a and a bit line plug 144b are formed as respectively occupying the upper opening 142a and bit line contact hole 142b. The wiring and bit line plugs 144a and 144b may include at least one material selected from the group consisting of a doped polysilicon, pure metals (e.g., titanium, tantalum, and tungsten) and conductive metal nitrides (e.g., titanium nitride and tantalum nitride).

A third conductive layer and a cap dielectric are formed in sequence on the second interlayer dielectric 140, and the cap dielectric and third conductive layer are successively patterned to form wiring 146a and a bit line 146b. Thus, the wiring 146a is formed over the first region 50 of the substrate 100, and contacts the upper surface of the wiring plug 144a. Similarly, the bit line 146b is thus formed over the second region 60 of the substrate 100, and contacts the upper surface of the bit line plug 144b. A wiring cap pattern 148 is formed on the wiring 146a. Likewise, a wiring cap pattern is formed on the bit line 146b. The wiring cap patterns are formed by forming a dielectric layer on the second interlayer dielectric 140 and patterning the dielectric layer.

Then, a wiring spacer dielectric having a substantially uniform thickness is formed over the entire surface of the substrate 100, and the wiring spacer dielectric is anisotropically etched to form a wiring spacer 150 on the sidewalls of the wiring 146a, and a wiring spacer on the sidewalls of the bit line 146b.

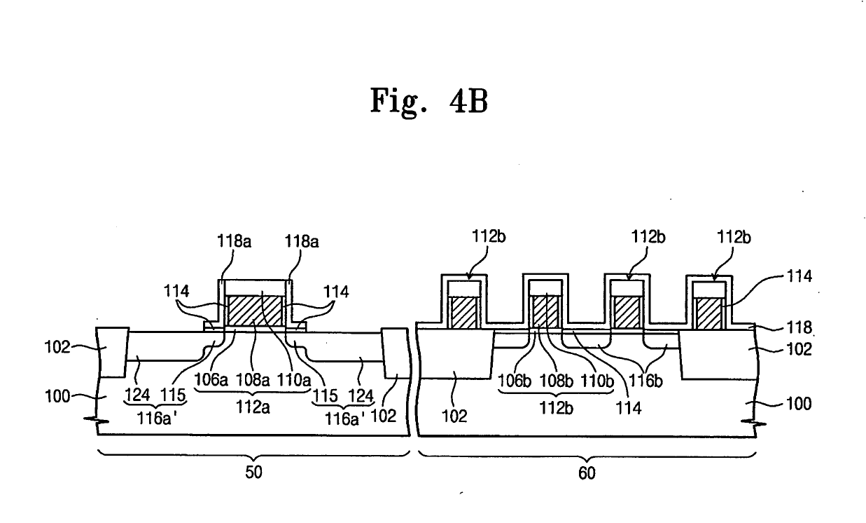

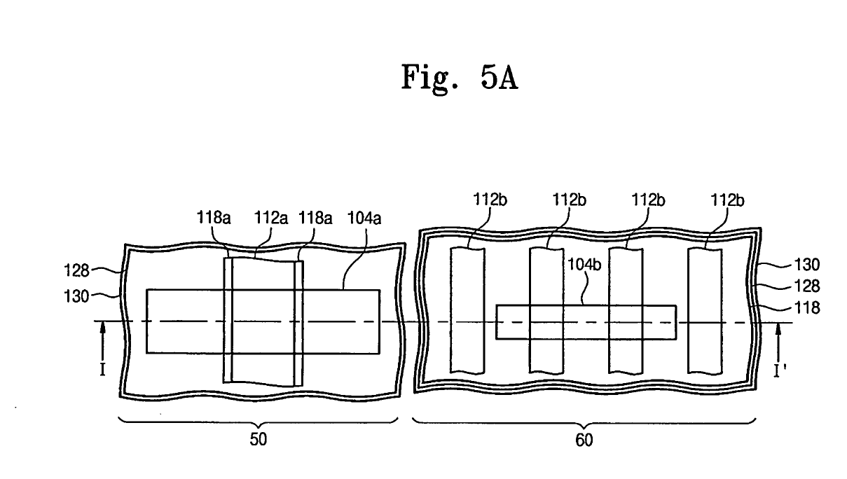

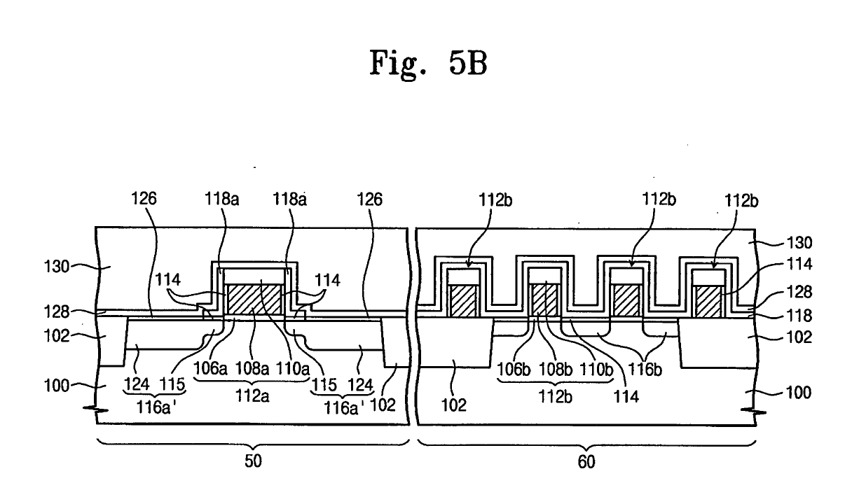

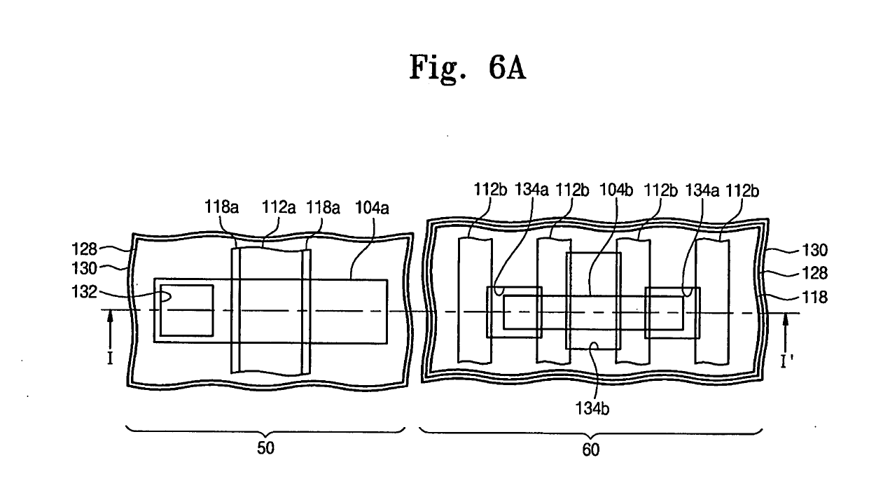

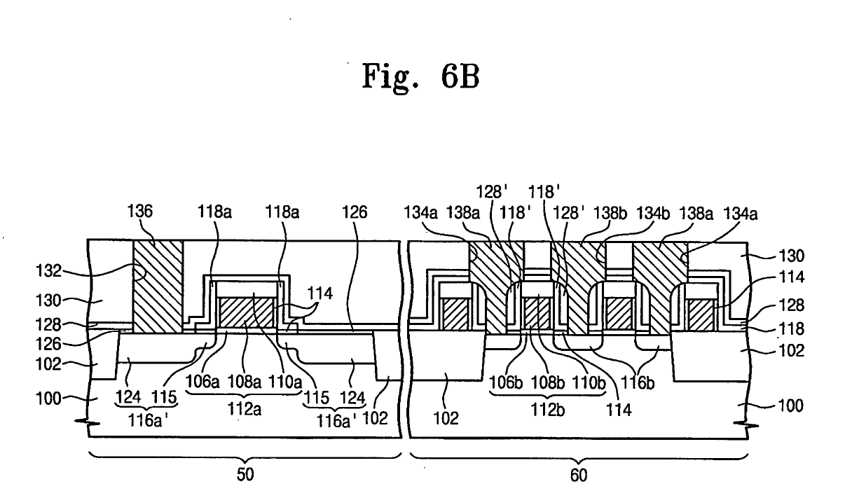

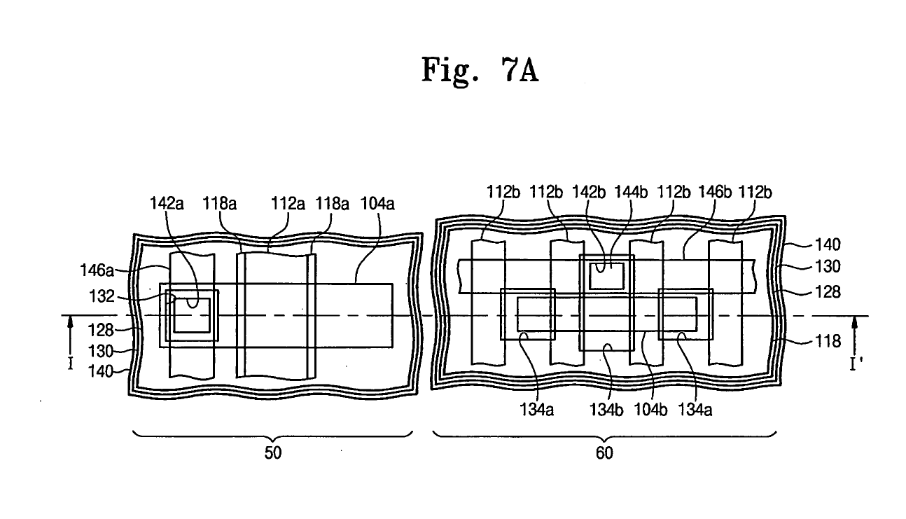

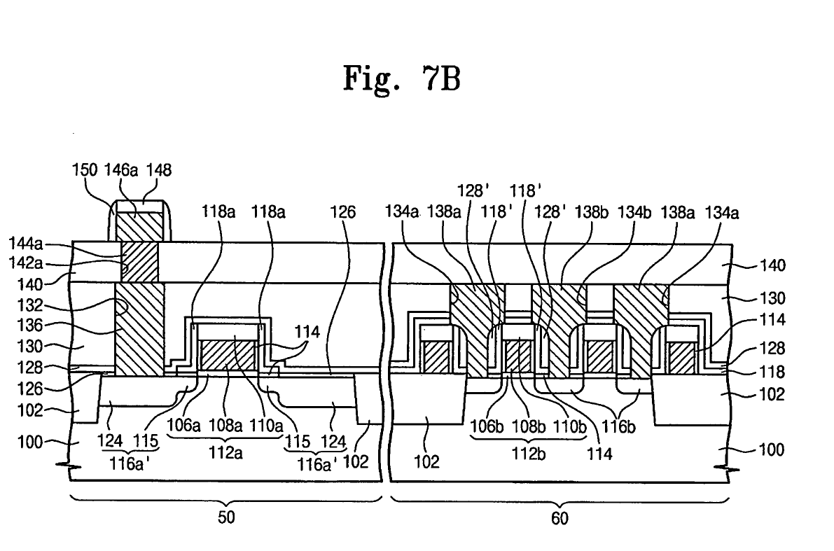

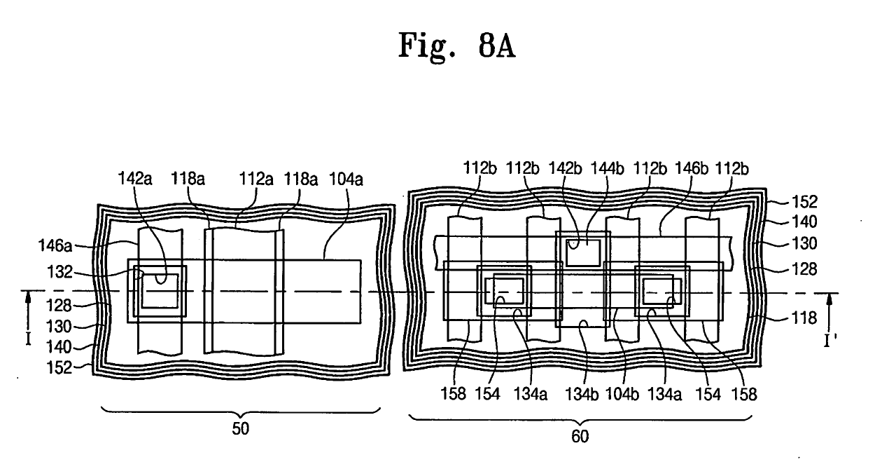

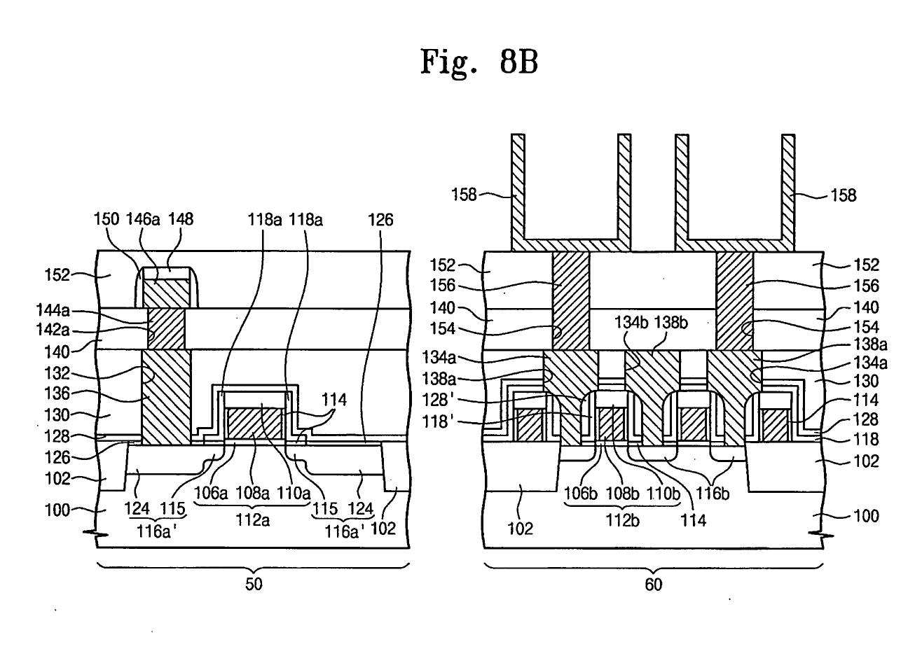

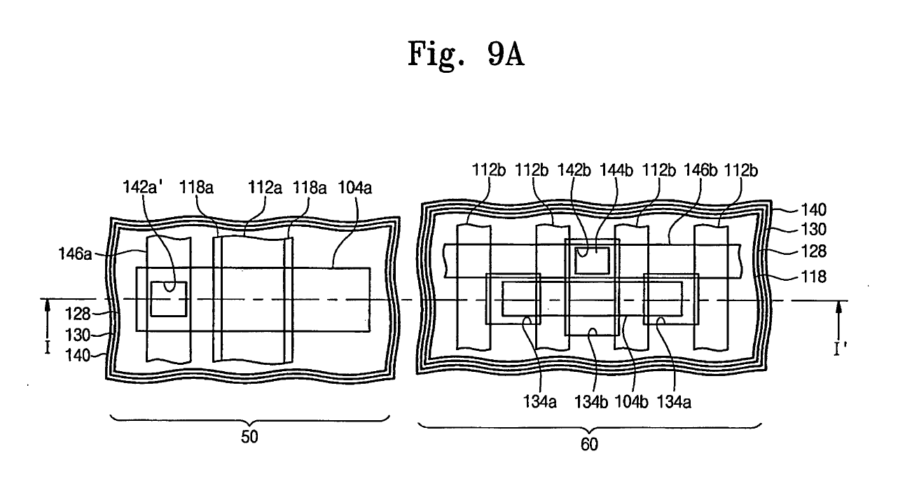

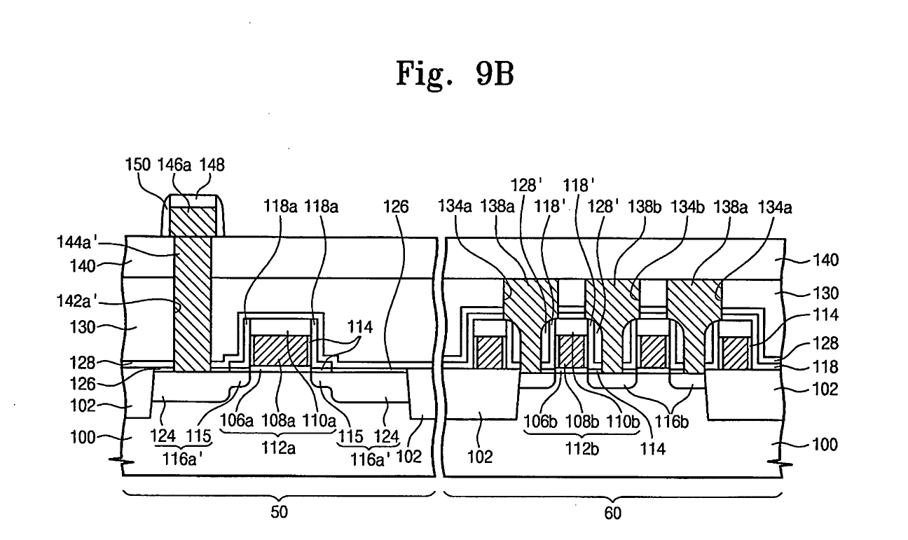

Referring again to FIGS. 6A, 6B, 7A, and 7B, the conductive plug 136 and the wiring plug 144a are used to electrically connect the wiring 146a and the first source/drain electrode region 116a′. Alternatively, the wiring 146a and the first source/drain region 116a′ may be electrically connected by another means such as that described as follows with reference to FIGS. 9A and 9B.

According to this method, the first interlayer dielectric 130 is formed as shown in and described above with respect to FIGS. 5A and 5B. Next, the first and second landing pads 138a and 138b are formed as shown in and described above with respect to FIGS. 6A and 6B. However, in this case, the lower opening 132 is not formed. Next, the second interlayer dielectric 140 is formed over the entire surface of the substrate 100.

Next, the second interlayer dielectric 140 on the first region 50, the first interlayer dielectric 130, the etch stop layer 128, and the buffer insulating layer 118 are successively patterned to form an opening 142a′ exposing the first source/drain region 116a′. Also, the second interlayer dielectric 140 on the second region 60 is patterned to form a bit line contact hole 142b exposing the second landing pad 138b. The opening 142a′ and bit line contact hole 142b may be formed simultaneously. In this case, the second landing pad 138b can function as an etch barrier during the etching of the first interlayer dielectric 130, the etch stop layer 128, and the buffer insulating layer 118 to form the opening 142a′.

Next, a second conductive layer is formed to fill the opening 142a′ and bit line contact hole 142b, and the second conductive layer is planarized until the second interlayer dielectric 140 is exposed. As a result, a wiring plug 144a′ occupying the opening 142a′ and a bit line plug 144b occupying the bit line contact hole 142b are formed. The wiring plug 144a′ may be formed of the same material as the wiring plug 144a described with reference to FIGS. 7A and 7B. The method of forming the wiring 146a and bit line 146b on the second interlayer dielectric 140 may be performed in the same way as described above with reference to FIGS. 7A and 7A.

In either case, and now referring to FIGS. 8A and 8B, a third interlayer dielectric 152 is formed over the entire substrate 100 including over the wiring 146a and bit line 146b. The third interlayer dielectric 152 may be a CVD oxide layer. The wiring cap pattern 148 and wiring spacer 150 may be formed of an insulating material having an etch selectivity with respect to the third interlayer dielectric 152. For example, the wiring cap pattern 148 and the wiring spacer 150 may be formed of a silicon nitride layer, or a silicon oxide nitride layer.

The third and second interlayer dielectrics 152 and 140 on the second region 60 are successively patterned to form a buried contact hole 154 exposing the first landing pad 138a. A buried contact plug 156 is formed to fill the buried contact hole 154. The buried contact plug 156 may include at least one material selected from the group consisting of doped polysilicon, pure metals (e.g., titanium, tantalum, and tungsten) and conductive metal nitrides (e.g., titanium nitride and tantalum nitride). Using the wiring cap pattern on the bit line 144b and/or the wiring spacer, the buried contact plug 156 can be self-aligned with the first landing pad 138a. The upper surface of the buried contact plug 156 is coplanar with the upper surface of the third interlayer dielectric 152.

A storage electrode 158 is formed on the third interlayer dielectric 152 on the second region 60. The storage electrode 158 contacts the upper surface of the buried contact plug 156. The storage electrode 158 may be cylindrical. The storage electrode 158 preferably includes at least one material selected from the group consisting of a doped silicon, pure metals, transition metals, conductive metal oxides (e.g., aluminum oxide), and conductive metal nitrides (e.g., titanium nitride and tantalum nitride).

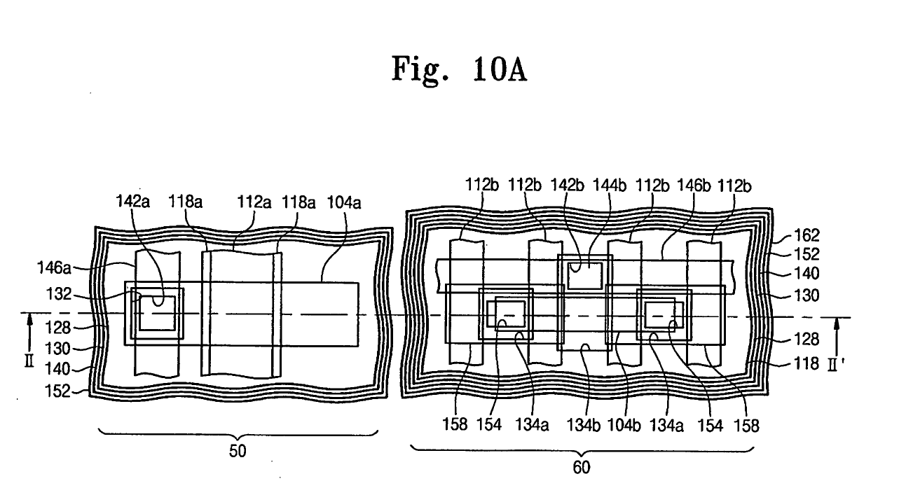

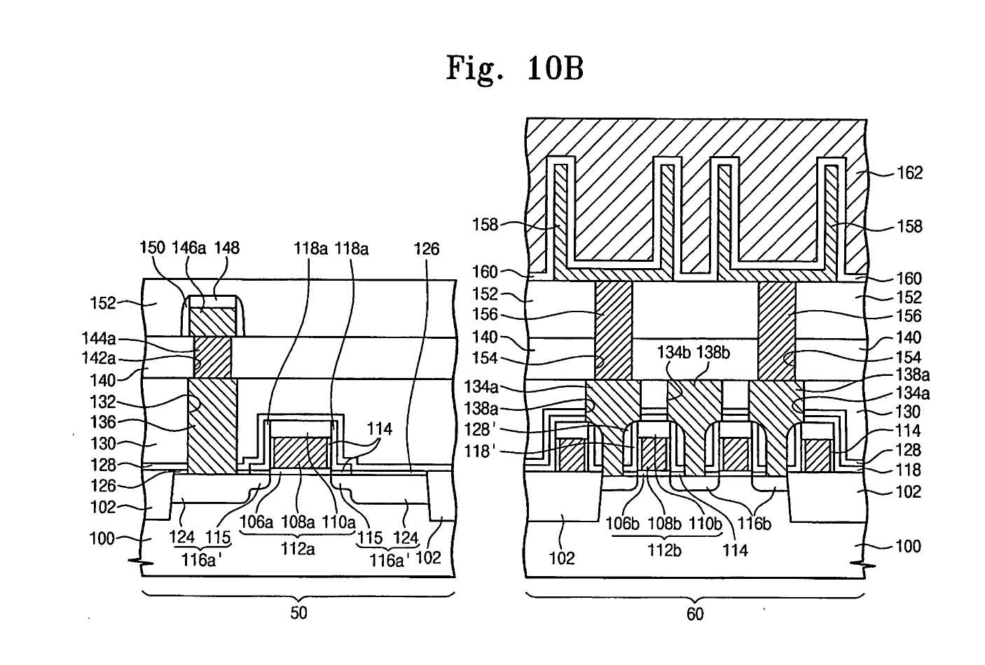

Next (refer to FIG. 10B), a capacitor dielectric 160 is formed on the surface of the storage electrode 158, and a plate electrode 162 (in FIG. 10b) is formed on the capacitor dielectric 160 so as to extend over the storage electrode 158. The storage electrode 158, plate electrode 162, and capacitor dielectric 160 form a capacitor

Next, semiconductor devices according to the present invention, and which may be fabricated according to the sequence of processes described above, will be described with reference to FIGS. 10A and 10B.

The device isolation layer 102 is disposed at the upper surface of the substrate 100 to demarcate the first active region 104a in the first region 50 of the substrate, and to demarcate the second active region 104b in the second region 60 of the substrate. As described with reference to FIG. 1A, a plurality of second active regions 104b may be demarcated within the second region 60 by the device isolation layer 102.

The first gate pattern 112a crosses over the first active region 104a, and one or several parallel second gate pattern 112b crosses/cross over the second active region 104b. Each second gate pattern 112b may extend linearly.

An L-shaped gate spacer 118a is disposed at both sides of the first gate pattern 112a. The spacer layer 118, from which the L-shaped gate spacer 11 8a was formed, covers the second region 60 of the substrate 100 and has a substantially uniform thickness. That is, the spacer layer 118 covers the device isolation layer 102, the second active region 104b, and the second gate pattern 112b in a conformal manner. The materials forming the spacer layer 118 and the gate spacer 118a have been described above and therefore, will not be re-described.

The first source/drain region 116a′ is disposed on the first active region 104a at both sides of the first gate pattern 112a, and the second source/drain region 116b is disposed on the second active region 104b at both sides of the second gate pattern 112b. The first source/drain region 116a′ includes the low concentration region 115 and the high concentration region 124. The high concentration region 124 has a higher density of dopant than the low concentration region 115. The low concentration region 115 is disposed below the gate spacer 118a.

The oxide layer 114 is disposed between the gate spacer 118a and the first active region 104a. The oxide layer 114 may also be disposed on the sidewalls of the first and second gate electrodes 108a and 108b of the first and second gate patterns 112a and 112b. The oxide layer 114 disposed on the sidewall of the first gate electrode 108a is interposed between the gate spacer 118a and the first gate electrode 108a. The oxide layer 114 disposed on the sidewall of the second gate electrode 108b is interposed between the spacer layer 118 and the second gate electrode 108b. The oxide layer 114 is also interposed between the spacer layer 118 and the second active region 104b.

The buffer insulating layer 126 is disposed on the first active region 104a beside the gate spacer 118a. In this respect, the buffer insulating layer 126 is restricted to being disposed on the first region 50 of the substrate 100. That is, among the first and second active regions 104a, 104b, the buffer insulating layer is only disposed on the first active region 104a. The buffer insulating layer 126 may be an oxide layer formed by a selective growth process. For example, the buffer insulating layer 126 may be formed as an oxide layer through a wet oxidation process or a thermal oxidation process. As described with reference to FIGS. 5A and 5B, the gate spacer 118a and the spacer layer 118 are formed of an insulating material that prevents the growth of the buffer insulating layer 126 thereon.

The etch stop layer 128 is disposed over the entire surface of the substrate 100, and the first interlayer dielectric 130 is formed on the etch stop layer 128. The etch stop layer 128 may be formed as a conformal layer. Also, the etch stop layer 128 physically contacts the gate spacer 118a, the buffer insulating layer 126, and the spacer layer 118.

The conductive plug 136 passes through the first interlayer dielectric 130, the etch stop layer 128, and the buffer insulating layer 126 so as to contact the first source/drain region 116a′, and in particular, the high concentration region 124, in the first region 50 of the substrate 100. Thus, the conductive plug 136 is disposed beside the gate spacer 118a. The first landing pad 138a and the second landing pad 138b each pass through the first interlayer dielectric 130, the etch stop layer 128, and the oxide layer 114. The first landing pad 13 8a contacts the first source/drain region 116a of the second gate pattern 112b, and the second landing pad 138b contacts the second source/drain region 116b of the second gate pattern 112b. The upper surfaces of the conductive plug 136, first landing pad 138a, second landing pad 138b, and first interlayer dielectric 130 may be coplanar.

The etch stop layer 128 and spacer layer 118 have spacer-shaped sections 128′ and 118′ disposed on the sidewalls of the second gate patterns 112b. The oxide layer 114 is interposed between the spacer-shaped sections 128′ and 118′ disposed on the sidewall of each second gate pattern 112b and the second active region 104b.

The second interlayer dielectric 140 is disposed on the first interlayer dielectric 130. The wiring plug 144a and the bit line plug 144b each extend (vertically) through the second interlayer dielectric 140. The wiring plug 144a contacts the upper surface of the conductive plug 136, and the bit line plug 144b contacts the second landing plug 138b.

The wiring 146a is disposed on the second interlayer dielectric 140 above the first region 50 of the substrate and contacts the upper surface of the wiring plug 144a, and the bit line 146b is disposed on the second interlayer dielectric 140 above the second region 60 of the substrate and contacts the bit line plug 144b. The wiring spacer 150 is disposed on sidewalls of the wiring 144a, and a similar wiring spacer is disposed on sidewalls of the bit line 144b. The wiring 146a is electrically connected through the wiring plug 144a and the conductive plug 136 to the first source/drain region 116a′. Alternatively, as illustrated in FIGS. 9A and 9B, the wiring 146a is electrically connected to the first source/drain region 116a′ by the wiring plug 144a′ passing sequentially through the second and first interlayer dielectrics 140 and 130.

Again, with reference to FIGS. 10A and 10B, the third interlayer dielectric 152 is disposed on the second interlayer dielectric 140. The buried plug 156 sequentially passes through the third and second interlayer dielectrics 152 and 140. The buried plug 156 contacts the first landing pad 138a.

The storage node 158 is disposed on the third interlayer dielectric 152 and contacts the upper surface of the buried plug 156. The storage node 158 may be cylindrical. The capacitor dielectric 160 covers the surface of the storage node 158 in a conformal manner. The capacitor dielectric 160 may include at least one material selected from the group consisting of an oxide layer, an oxide-nitride-oxide (ONO) layer, and a high-k dielectric layer. A high-k dielectric layer refers to any dielectric whose dielectric constant is higher than that of silicon nitride. For example, high-k dielectrics include hafnium oxide and aluminum oxide.

The plate electrode 162 is disposed on the capacitor dielectric 160. The plate electrode 162 covers the surface of the storage electrode 158. The storage electrode 158, plate electrode 162, and capacitor dielectric 160 form a capacitor.

In the above-described embodiments, the second region 60 is described as a region in which DRAM cells are formed. However, the present invention is not so limited. That is, the second region 60 may have other types of memory cells formed thereon with finely-spaced gate patterns. For example, the second region 60 may have phase-shift memory cells, flash memory cells, and/or static random access memory (SRAM) cells formed thereon. If flash memory cells are formed on the second region 60, the second gate pattern formed in the second region 60 may include a tunnel dielectric, a charge storage pattern, a blocking dielectric pattern, and a control gate electrode sequentially stacked one atop the other.

As described above, according to the present invention, the first and second spacer layers are used to establish the width of the low concentration region of the first source/drain region within the first region of the substrate, and then the second spacer layer is removed to reduce the aspect ratio of the gap region between the second gate patterns formed on the second region of the substrate. Thus, the formation of voids in the gap region can be prevented.

Also, after the second spacer layer is removed, a buffer insulating layer is formed on the first active region (the active region within the first region of the substrate) by a selective growth process. The buffer insulating layer functions as a buffer to alleviate stress between the etch stop layer and the first active region. Furthermore, due to the selective growth process, the buffer insulating layer is not formed on the second region of the substrate. Accordingly, the low aspect ratio of the gap region is maintained to ensure that voids are not formed in the gap region. Additionally, the selective growth process helps to minimize the overall number of processes used to manufacture the device. Hence, a high yield of such semiconductor devices can be realized.

Finally, although the present invention has been described above in connection with the preferred embodiments thereof, the present invention is not limited to the disclosed embodiments. Rather, modifications, enhancements, and other changes to the disclosed embodiments may fall within the true spirit and scope of the present invention as defined by the appended claims.

What is claimed is:

1. A method of manufacturing a semiconductor device, comprising:
forming a device isolation layer at a surface of a substrate such that the device isolation layer demarcates a first active region in a first region of the substrate and a second active region in a second region of the substrate;
forming a first gate pattern and at least one second gate pattern on the first active region and the second active region, respectively;
sequentially forming a first spacer layer and then a second spacer layer over the first and second gate patterns on the substrate;
anisotropically etching the second and first spacer layers on the first region of the substrate to form a gate spacer having a lower spacer section and an upper spacer section on each sidewall of the first gate pattern, and wherein the anisotropic etching is carried out selectively to leave the second and first spacer layers on the second region of the substrate;
subsequently removing the upper spacer section of the gate spacer from each sidewall of the first gate pattern, and the second spacer layer from the second region;
performing a selective growth process which grows insulating material on the first active region, beside the lower spacer section disposed on each sidewall of the first gate pattern, and without growing any insulating material on the second region of the substrate to thereby form a buffer insulating layer on the first active region; and
subsequently forming an etch stop layer on the substrate, and forming an interlayer dielectric on the etch stop layer.

2. The method of claim 1, wherein the performing of the selective growth process comprises performing a wet oxidation process.

3. The method of claim 2, wherein the wet oxidation process comprises exposing the substrate to an oxidation solution including hydrogen peroxide.

4. The method of claim 3, wherein the oxidation solution further includes sulfuric acid.

5. The method of claim 1, wherein the performing of the selective growth process comprises subjecting the substrate to a thermal oxidation process.

6. The method of claim 1, wherein the forming of the first spacer layer comprises forming the first spacer layer of an insulating material, and the selective growth process is a process by which the insulating material constituting the buffer insulating layer will not grow on the insulating material of the first pacer layer.

7. The method of claim 1, wherein the forming of the buffer insulating layer comprises forming the buffer insulating layer to a thickness of from about 5 Å to about 50 Å.

8. The method of claim 1, further comprising performing a gate oxidation process on the substrate before the first spacer layer is formed, the performing of the gate oxidation process including forming an oxide layer on the first and second active regions on both sides of each of the first and second gate patterns, and
wherein the oxide layer is left on the first active region beside the lower spacer section on each sidewall of the first gate pattern after the anisotropic etching of the second and first spacer layers, and the oxide layer is subsequently removed from the first active region together with the upper spacer section from each sidewall of the first gate pattern and the second spacer layer from the second region.

9. The method of claim 1, wherein the forming of the etch stop layer comprises forming a nitride layer on the substrate.

10. The method of claim 1, further comprising:
implanting first dopant ions into the first active region, before the first spacer layer is formed, to form a first source/drain region at both sides of the first gate pattern;
implanting second dopant ions into the second active region, before the first spacer layer is formed, to form a second source/drain region at both sides of the second gate pattern; and
implanting third dopant ions into the first source/drain region using the gate spacer and the first gate pattern as masks, wherein the third dopant ions are implanted at a higher dose than the first dopant ions.

11. The method of claim 1, further comprising:
forming an opening through the interlayer dielectric, the etch stop layer, and the buffer insulating layer on the first region such that the opening exposes the first active region at one side of the first gate pattern; and
filling the opening with conductive material.

12. The method of claim 11, further comprising:
simultaneously forming with the opening a first land opening and a second land opening, each through the interlayer dielectric, the etch stop layer, and the first spacer layer in the second region, such that the first and second land openings expose the second active region at first and second sides of the second gate pattern, respectively; and
filling the first and second land openings with conductive material to form a first landing pad and a second landing pad occupying the first and second land openings, respectively.

13. The method of claim 11, further comprising:
forming a first land opening and a second land opening, each through the interlayer dielectric, the etch stop layer, and the first spacer layer in the second region, such that the first and second land openings expose the second active region at first and second sides of the second gate pattern, respectively; and
filling the first and second land openings with conductive material to form a first landing pad and a second landing pad occupying the first and second land openings, respectively; and
forming a second interlayer dielectric that covers the first and second landing pads.

14. The method of claim 12, further comprising:
forming a bit line electrically connected to the first landing pad; and
forming a capacitor electrically connected to the second landing pad.

15. The method of claim 12, wherein the forming of the at least one second gate pattern comprises forming a plurality of second gate patterns each including a gate dielectric, a gate electrode, and a gate cap stacked one atop the other in the foregoing sequence, and
the forming of the first and second land openings is carried out such that each of the first and second landing pads is formed each between confronting sidewalls of the second gate patterns in self-alignment with the second active region.

16. A method of manufacturing a semiconductor device, comprising:
forming a device isolation layer at a surface of a substrate such that the device isolation layer demarcates a first active region in a first region of the substrate and a second active region in a second region of the substrate;
forming a first gate pattern on the first active region and a plurality of second gate patterns on the second active region;
sequentially forming at least one spacer layer over the first and second gate patterns on the substrate;
anisotropically etching the at least one spacer layer on the first region of the substrate to form a gate spacer on each sidewall of the first gate pattern, and wherein the anisotropic etching is carried out selectively to leave the at least one spacer layer on the second region of the substrate;
implanting dopant ions into the first active region using the first gate pattern and the gate spacer as a mask;
subsequently simultaneously etching the at least one spacer layer on the first and second active regions, thereby decreasing the aspect ratio of gap regions each constituting a space between adjacent ones of the second gate patterns; and
subsequently forming an interlayer dielectric on the substrate.

17. The method of claim 16, wherein the forming of the at least one spacer layer comprises sequentially forming first and second spacer layers, the anisotropic etching is carried out to form the gate spacer as having a lower spacer section and an upper spacer section on each sidewall of the first gate pattern, and the anisotropic etching is carried out selectively to leave the second and first spacer layers on the second region of the substrate; and further comprising:
removing the upper spacer section of the gate spacer from each sidewall of the first gate pattern, and the second spacer layer from the second region after the dopant ions are implanted into the first active region;
subsequently performing a selective growth process which grows insulating material on the first active region, beside the lower spacer section disposed on each sidewall of the first gate pattern, and without growing any insulating material on the second region of the substrate to thereby form a buffer insulating layer on the first active region without increasing the aspect ratio of the gap region; and
forming an etch stop layer on the substrate including over the buffer insulating layer before the interlayer dielectric is formed.

18. The method of claim 17, further comprising:
implanting first dopant ions into the first active region, before the first spacer layer is formed, to form a first source/drain region at both sides of the first gate pattern; and
implanting second dopant ions into the second active region, before the first spacer layer is formed, to form a second source/drain region at both sides of each of the second gate patterns.

19. A semiconductor device comprising:
a substrate;
a device isolation layer disposed at an upper surface of the substrate and demarcating a first active region in a first region of the substrate and a second active region in a second region of the substrate;
a first gate pattern and a second gate pattern respectively disposed on the first active region and the second active region;
a gate spacer having L-shaped sections disposed sidewalls of the first gate pattern, respectively;
a buffer insulating layer disposed on the first active region beside the gate spacer;
a spacer layer conformally covering the second gate pattern on the second region and the second active region, and the spacer layer being of the same material as the L-shaped sections of the gate spacer;
an etch stop layer covering the first and second gate patterns on the substrate; and
an interlayer dielectric disposed on the etch stop layer.

20. The semiconductor device of claim 19, wherein the etch stop layer contacts the buffer insulating layer, the gate spacer, and the spacer layer.

21. The semiconductor device of claim 19, wherein the buffer insulating layer is an oxide layer.

22. The semiconductor device of claim 19, wherein the etch stop layer is a nitride layer.

23. The semiconductor device of claim 19, further comprising:
a first source/drain region at both sides of the first gate pattern on the first active region; and
a second source/drain region at both sides of the second gate pattern on the second active region, and
wherein the first source/drain region includes a low concentration region containing dopant, and a high concentration region containing dopant at a concentration higher than the concentration of the dopant in the low concentration region, and
the second source/drain region has a substantially uniform dopant concentration.

24. The semiconductor device of claim 19, further comprising an oxide layer interposed between the gate spacer and the first active region, and between the spacer layer and the second active region.

25. The semiconductor device of claim 19, further comprising a conductive body extending through the interlayer dielectric, the etch stop layer, and the buffer insulating layer in the first region, and contacting the first active region at one side of the first gate pattern.

26. The semiconductor device of claim 25, further comprising a first landing pad and a second landing pad extending through the interlayer dielectric, the etch stop layer, and the spacer layer, each of the first and second landing pads contacting the second active region at a respective side of the second gate pattern, and wherein upper surfaces of the conductive body, the first and second landing pads, and the interlayer dielectric are coplanar.

27. The semiconductor device of claim 25, further comprising:
a first landing pad and a second landing pad each extending through the dielectric layer, the etch stop layer, and the spacer layer on the second region, each of the first and second landing pads contacting the second active region at a respective side of the second gate pattern; and
a second interlayer dielectric covering the first and second landing pads.

28. The semiconductor device of claim 26, further comprising:
a bit line electrically contacting the first landing pad; and
a capacitor electrically contacting the second landing pad.

29. The semiconductor device of claim 26, wherein
the second gate pattern comprises a gate dielectric, a gate electrode, and a cap dielectric pattern stacked one atop the other in the foregoing sequence, and
the first and second landing pads each contact the etch stop layer.
